(19) United States
(12) Patent Application Publication
(10) Pub. No.: US 2020/0283627 A1
(43) Pub. Date: Sep. 10, 2020

(54) CURABLE ORGANOSILICON RESIN COMPOSITION

(71) Applicant: Shin-Etsu Chemical Co., Ltd., Tokyo (JP)

(72) Inventor: Tomoyuki MIZUNASHI, Annaka-shi (JP)

(73) Assignee: Shin-Etsu Chemical Co., Ltd., Tokyo (JP)

(21) Appl. No.: 16/807,696

(22) Filed: Mar. 3, 2020

(30) Foreign Application Priority Data
Mar. 6, 2019 (JP) 2019-040172

(51) Int. Cl. C08L 83/04; H01L 51/00; C08G 77/12; C08G 77/14; C08G 77/08; C08G 77/04

(52) U.S. Cl. CPC C08L 83/04; H01L 51/0094; C08G 77/12; C08K 3/013; C08G 77/08; C08G 77/045; C08G 77/14

(57) ABSTRACT

Resin composition of (A) an organopolysiloxane having at least two alkenyl groups bonded to a silicon atom, and 0.1 to 30 mol % of R²R³SiO_{2/2} units based on the total mole of siloxane units and an SiO_{4/2} unit and a R¹SiO_{3/2} unit, wherein the total mole of the SiO_{4/2} unit and the R¹SiO_{3/2} unit is 50 mol % or more based on the total mole of the siloxane units, wherein a hydroxyl group is bonded to a silicon atom in an amount of at least 0.001 mol/100 g of the organopolysiloxane; (B) an organohydrogenpolysiloxane having at least two hydrogen atoms each bonded to a silicon atom and at least one aromatic hydrocarbon groups each bonded to a silicon atom at a ratio of the number of the hydrosilyl group in component (B) to the number of the alkenyl group in component (A) is 0.1 to 4.0; and (C) a platinum group metal catalyst.

### CROSS REFERENCE

This application claims the benefits of Japanese Patent Application No. 2019-040172 filed on Mar. 6, 2019, the contents of which are herein incorporated by reference.

### FIELD OF THE INVENTION

The present invention relates to a curable organosilicon resin composition and a semiconductor device.

LED encapsulating materials are required to be excellent in heat resistance, light resistance, workability, adhesiveness, gas barrier property, and curing properties. Therefore, thermoplastic resins such as epoxy resins, poly(meth)acrylates and polycarbonates have been frequently used. However, because of high-output of LED light emitting devices in the recent years, problems have been found in heat resistance and discoloration resistance when these thermoplastic resins are used in a high temperature environment for a long period of time.

Recently, a lead-free solder has been often used to solder optical elements to substrates. The lead-free solder has a higher melting temperature than conventional solders, and is usually used at a temperature of 260 degrees C. or higher. However, it has been found that when soldering is carried out at such a high temperature, the conventional encapsulating materials, thermoplastic resins, deform or yellow.

Thus, with the increasing output of the LED light-emitting devices and the use of the lead-free solder, encapsulating materials are required to have higher heat resistance. Patent Literatures 1 and 2 describe optical resin compositions comprising a thermoplastic resin and nanosilica in order to improve heat resistance. However, the heat resistances of those thermoplastic resin compositions are still insufficient.

A thermosetting silicone resin has been considered as an encapsulating material for LEDs because of its excellent heat resistance, light resistance and light transmittance, as described in Patent Literatures 3 to 5. However, the silicone resin has disadvantages in that the strength of the resin is larger than that of the epoxy resin. Its gas permeability is large, that is, the gas barrier property is low, so that the luminance is decreased due to sulfurization of the electrodes.

Further, when a silicone resin containing a silicate-based fluorescent substance is used as an encapsulating material for an LED, there are problems that water vapor penetrates into the encapsulating silicone resin having a low gas barrier property, and water reacts with the fluorescent substance on a surface to decompose, the fluorescent substance, so that the fluorescent characteristics are remarkably deteriorated. Thus, when the conventional silicone resin is used as an encapsulating material for LEDs, there are the problems that the luminance decreases due to the sulfurization of the electrodes and, further, long-term reliability of the LEDs under high humidity is lowered. Therefore, improvement of a gas barrier property of a silicone resin is increasingly required.

To solve aforesaid problems, Patent Literatures 6 and 7 describe the introduction of an aromatic substituent, such as a phenyl group, in a silicone resin in order to increase a refractive index and improve the gas barrier property. However, another problem occurs that heat resistance is deteriorated with the introduction of aromatic substituent.

### PRIOR LITERATURES

### Patent Literatures

[Patent Literature 1] Japanese Patent Application Laid-Open No. 2012-214554

[Patent Literature 2] Japanese Patent Application Laid-Open No. 2013-204029

[Patent Literature 3] Japanese Patent Application Laid-Open No. 2006-213789

[Patent Literature 4] Japanese Patent Application Laid-Open No. 2007-131694

[Patent Literature 5] Japanese Patent Application Laid-Open No. 2011-252175

[Patent Literature 6] Japanese Patent Application Laid-Open No. 2014-88513

[Patent Literature 7] WO2013/005859.

### DISCLOSURE OF THE INVENTION

### Problems to be Solved by the Invention

One of the purposes of the present invention is to provide a curable organosilicon resin composition which has excellent heat resistance and gas barrier property and to provide an optical semiconductor device encapsulated with the composition.

### Means to Solve the Problems

The present invention has been made in view of the above-mentioned problems and the present inventors have found that a curable organopolysiloxane resin composition which comprises a branched- or resin-structure organopolysiloxane having the specific amount of D units having an alkenyl group (i.e., R²R³SiO_{2/2} units) and a total 50 mol % or more of Q units and T units provides a cured product having a high heat resistance and an excellent gas barrier property.

That is, the present invention provides a curable organosilicon resin composition comprising.

(A) an organopolysiloxane having at least two alkenyl groups each bonded to a silicon atom, and comprising 0.1 to 30 mol % of R²R³SiO_{2/2} units based on the total mole of siloxane units and at least one out of an SiO_{4/2} unit and a R¹SiO_{3/2} unit, wherein the total mole of the SiO_{4/2} unit and the R¹SiO_{3/2} unit 50 mol % or more based on the total mole of the siloxane units,

wherein, R¹ is, independently of each other, a substituted or unsubstituted alkyl group having 1 to 10 carbon atoms, an alkenyl group having 2 to 10 carbon atoms, or an aromatic hydrocarbon group having 6 to 10 carbon atoms, R² is, independently of each other, an alkenyl group having 2 to 10 carbon atoms, and R³ is, independently of each other, a substituted or unsubstituted alkyl group having 1 to 10 carbon atoms, or an aromatic hydrocarbon group having 6 to 10 carbon atoms,

wherein a hydroxyl group is bonded to a silicon atom in an amount of at least 0.001 mol/100 g of the organopolysiloxane;

(B) an organohydrogenpolysiloxane having at least two hydrogen atoms each bonded to a silicon atom and at least one aromatic hydrocarbon groups each bonded to a silicon atom in an amount such that a ratio of the number of the hydrosilyl group in component (B) to the number of the alkenyl group in component (A) is 0.1 to 4.0; and

(C) a platinum group metal catalyst in a catalytic amount.

### Effects of the Invention

The curable organosilicon resin composition of the present invention provides a cured product having excellent gas barrier property, heat resistance and mechanical properties.

### BEST MODE OF THE INVENTION

The present invention will be described below in detail.

### [(A) Organopolysiloxane]

Component (A) is an organopolysiloxane having a branched or resin structure and is a main component of the present curable organosilicon resin composition. Component (A) comprises at least one out of an SiO_{4/2} unit (Q unit) and a R¹SiO_{3/2} unit (T unit), and the total mole of the Q unit and the T unit is 50 mol % or more, preferably 50 to 90 mol %, based on the total mole of the siloxane units. If the total mole of the Q unit and the T unit is less than the afore-mentioned lower limit, the gas barrier property of an obtained cured product deteriorates, which is not preferable. The mole amount of the Q unit is preferably in the range of 0 to 60 mol %, more preferably 0 to 50 mol %, more preferably 0.1 to 30 mol %, based on the total mole of the siloxane units. The mole amount of the T units is preferably 0 to 90 mol %, more preferably 30 to 80 mol %, based on the total mole of the siloxane units.

R¹ is, independently of each other, a substituted or unsubstituted alkyl group having 1 to 10 carbon atoms, an alkenyl group having 2 to 10 carbon atoms, or an aromatic hydrocarbon group having 6 to 10 carbon atoms. Preferably, R¹ is, independently of each other, an alkenyl group having 2 to 10 carbon atoms, more preferably 2 to 5 carbon atoms, a substituted or unsubstituted alkyl group having 1 to 10 carbon atoms, more preferably 1 to 5 carbon atoms, or an aromatic hydrocarbon group having 6 to 10 carbon atoms, more preferably 6 to 8 carbon atoms, such as, for example, lower alkyl groups such as a methyl, ethyl, propyl or butyl group; cycloalkyl groups such as a cyclohexyl group; aryl groups such as a phenyl, tolyl or xylyl group; aralkyl groups such as a benzyl, phenylethyl or phenylpropyl group; alkenyl groups such as a vinyl, allyl, propenyl, isopropenyl, butenyl, hexenyl, cyclohexenyl or octenyl group; and groups in which a part or all of the hydrogen atoms of the aforesaid alkyl group are substituted with a halogen atom, such as a fluorine, bromine or chlorine atom, or a cyano group, for example, a chloromethyl group, a cyanoethyl group and a 3,3,3-trifluoropropyl group. Among these, a methyl group and a phenyl group are preferable, and at least one of R¹ is preferably a phenyl group.

Further, component (A) is characterized in that the component comprises the specific amount of D units having an alkenyl group, i.e., R²R³SiO_{2/2} units. That is, component (A) has 0.1 to 30 mol %, preferably 0.2 to 10 mol %, of R²R³SiO_{2/2} units, based on the total moles of the siloxane units. If the amount of D units is less than 0.1 mol %, the effect of improving the heat resistance and the gas barrier property may not be obtained. If the amount of D units is more than 30 mol %, the crosslink density may be too high and the toughness may be lost. R² is, independently of each other, an alkenyl group having 2 to 10 carbon atoms, and R³ is, independently of each other, a substituted or unsubstituted alkyl group having 1 to 10 carbon atoms, or an aromatic hydrocarbon group having 6 to 10 carbon atoms.

Examples of R² includes alkenyl groups such as a vinyl group, an allyl group, a propenyl group, an isopropenyl group, a butenyl group, a hexenyl group, a cyclohexenyl group and an octenyl group. Among these, a vinyl group is preferable. Examples of R³ include lower alkyl groups such as a methyl, ethyl, propyl or butyl group; cycloalkyl groups such as a cyclohexyl group; aryl groups such as a phenyl, tolyl or xylyl group; and aralkyl groups such as a benzyl, phenylethyl or phenylpropyl group; and groups in which a part or all of the hydrogen atoms of the aforesaid alkyl groups are substituted with a halogen atom such as a fluorine, bromine or chlorine atom, or a cyano group, for example, a chloromethyl group, a cyanoethyl group and a 3,3,3-trifluoropropyl group.

Component (A) may comprise 0 to 50 mol %, preferably 0 to 20 mol %, of (R⁴)₂SiO_{2/2} unit as D unit having no alkenyl group, in addition to the R²R³SiO_{2/2} unit. Further, component (A) preferably comprises 0 to 50 mol %, more preferably 10 to 30 mol %, of (R⁵)₃SiO_{1/2} unit (M unit). The total amount of the siloxane units, i.e., Q units, T units, D units and M units, is 100 mol %.

R⁴ is, independently of each other, selected from the group consisting of substituted or unsubstituted alkyl groups having 1 to 10 carbon atoms and aromatic hydrocarbon groups having 6 to 10 carbon atoms. R⁵ is, independently of each other, selected from the group consisting of alkenyl groups having 2 to 10 carbon atoms, substituted or unsubstituted alkyl groups having 1 to 10 carbon atoms, and aromatic hydrocarbon groups having 6 to 10 carbon atoms. At least one of R⁵ is an alkenyl group having 2 to carbon atoms. R⁵ is, for instance, lower alkyl groups such as a methyl, ethyl, propyl or butyl group; cycloalkyl groups such as a cyclohexyl group; aryl groups such as a phenyl, tolyl or xylyl group; aralkyl groups such as a benzyl, phenylethyl or phenylpropyl group; alkenyl groups such as a vinyl, allyl, propenyl, isopropenyl, butenyl, hexenyl, cyclohexenyl or octenyl group; groups in which a part or all of the hydrogen atoms of the alkyl group are substituted with a halogen atom such as a fluorine, bromine or chlorine atom, or a cyano group, for example, a chloromethyl group, a cyanoethyl group, or a 3,3,3-trifluoropropyl group. In particular, R⁴ is preferably a methyl group or a phenyl group and R⁵ is preferably a methyl, phenyl or vinyl group.

Component (A) has at least two, preferably 2 to 6, silicon atom-bonded alkenyl groups per molecule. The amount of the alkenyl groups in component (A) is preferably 0.01 to 0.5 mol, more preferably 0.05 to 0.3 mol, and even more preferably 0.10 to 0.25 mol, per 100 g of component (A). When the amount of the alkenyl group meets the aforesaid lower limit, the composition has sufficient crosslinking points to solidify. When the amount of the alkenyl group meets the aforesaid upper limit, the crosslinking density is not excessive, so that the toughness of the cured product is not lost.

At least one of R¹, R³, R⁴ and R⁵ in component (A) is preferably an aromatic hydrocarbon group having 6 to 10 carbon atoms. The number of the aromatic hydrocarbon group is preferably 18 to 90 mol %, more preferably 20 to 88 mol %, further more preferably larger than 30 mol % to 85 mol %, further more preferably 40 mol % to 83 mol %, and most preferably 50 mol % to 82 mol %, based on the total number of the substituents each bonded to a silicon atom, i.e., R¹, R², R³, R⁴ and R⁵. On account of the fact that component (A) has the aromatic hydrocarbon group in the amount of the aforesaid range, the gas barrier property is improved, which is preferable. If the amount of the aromatic hydrocarbon group is too small, the strength of the cured resin may be lower.

Component (A) in the present invention comprises at least one of the SiO_{4/2} unit (Q unit) or the R¹SiO_{3/2} unit (T unit) When component (A) comprises both of the Q and T units, a mole ratio of the Q unit to the T unit is preferably 0.001 to 0.2, more preferably 0.001 to 0.15, further more preferably 0.003 to 0.13, most preferably 0.005 to 0.08. On account of the aforesaid mole ratio of the Q unit to the T unit, the crack resistance is improved, which is preferable.

Component (A) is characterized in that it has a hydroxyl group bonded to a silicon atom in an amount of 0.001 mol/100 g of component (A) or more. If the amount of the hydroxyl group bonded to a silicon atom is less than the aforesaid lower limit, the curable organosilicon resin composition may not adhere to a base substrate. The amount is, preferably, 0.005 mol/100 g or more, more preferably 0.008 mol/100 g or more, more preferably 0.01 mol/100 g or more. If the amount of the hydroxyl group bonded to a silicon atom is too large, a cured product may be too much tacky. Therefore, the upper limit of the amount is preferably 1.0 mol/100 g or less, more preferably 0.8 mol/100 g or less. On account of the specific amount of the hydroxyl group bonded to a silicon atom, a cured product may satisfy the required heat resistance and gas barrier property and shows less surface tackiness, which are the objects of the present invention.

In component (A), the amount of an alkoxy group having 1 to 10 carbon atoms, preferably 1 to 5 carbon atoms and bonded to a silicon atom is preferably 1.0 mol/100 g or less, more preferably 0.8 mol/100 g or less, further more preferably 0.5 mol/100 g or less. If the amount of the alkoxy group is more than the aforesaid upper limit, an alcohol gas generates as a by-product during curing to cause voids in a cured product. There is no lower limit and a smaller amount is more preferable. The amounts of the hydroxyl group and the alkoxy group each bonded to a silicon atom are determined by ¹H-NMR and ²⁹Si-NMR, respectively, in the present invention.

Component (A) preferably has a weight average molecular weight (Mw) of from 1,000 to 5,000, more preferably from 1,100 to 3,000. When the weight average molecular weight meets the aforesaid lower limit, the cured product may not be brittle. When the weight average molecular weight meets the aforesaid upper limit, there is no fear that a viscosity of the composition in too high so that the composition does not flow. In the present invention, the weight average molecular weight (Mw) is determined by gel permeation chromatography (GPC) in the following conditions and is reduced to polystyrene as a standard substance.

### [Measurement Conditions]

Developing solvent: Tetrahydrofuran (THF)

Flow rate: 0.6 mL/min.

Detector: Differential Refractive Index Detector (RI)

Columns: TSK Guardcolumn SuperH-L
TSKgel SuperH4000(6.0 mmI.D.×15 cm×1)
TSKgel SuperH3000(6.0 mmI.D.×15 cm×1)
   TSKgel SuperH2000(6.0 mmI.D.×15 cm×2)
(All manufactured by Tosoh, Co.)

Column Temperature: 40 degrees C.

Sample injection volume: 20 μL (THF solution in a 0.5% by mass concentration)

A method for preparing component (A) is not particularly limited. Component (A) is obtained, for example, by hydrolyzation-condensing silane compounds as raw materials for each of the constitution units. For example, the raw material for providing the SiO_{4/2} unit (Q unit) includes sodium silicate, tetraalkoxysilane or condensation products thereof, but is not limited to these.

Examples of the raw material for providing the R¹SiO_{3/2} unit (T unit) include organosilicon compounds such as organotrichlorosilanes and organotrialkoxysilanes which are represented by the following formulas, or condensation products thereof, but are not limited to these.

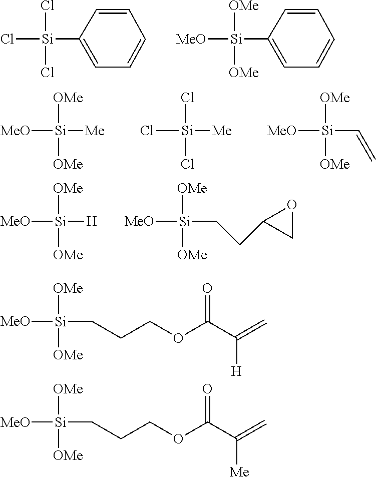

wherein “Me” represents a methyl group.

Examples of the raw material for providing the R²R³SiO_{2/2} unit (D unit) having an alkenyl group include organosilicon compounds such as diorganodichlorosilanes and diorganodialkoxysilanes which are represented by the following formulas, but are not limited to these.

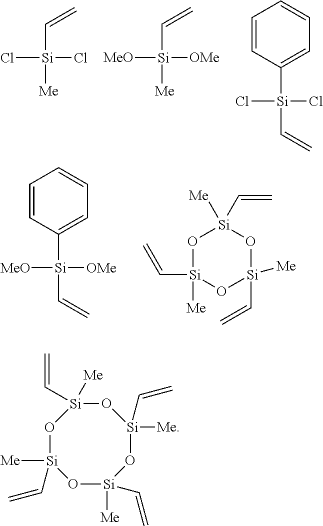

Examples of the raw material for providing the R⁴₂SiO_{2/2} unit (D unit) include organosilicon compounds such as diorganodichlorosilanes and diorganodialkoxysilanes which are represented by the following formulas, but are not limited to these.

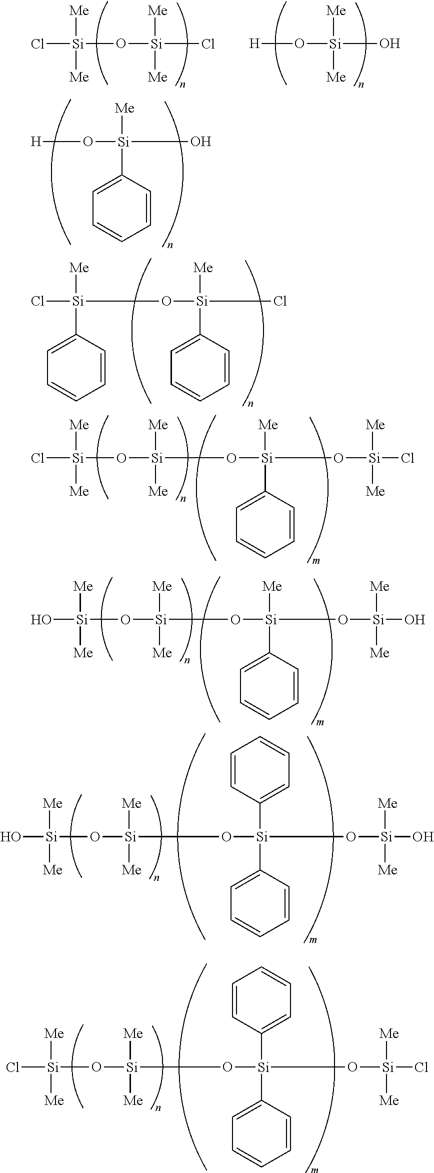

wherein “Me” represents a methyl group, n is an integer of 5 to 80, m is an integer of 5 to 80, and n+m<=78.

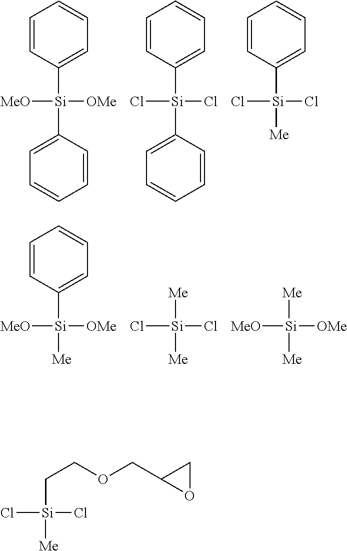

wherein “Me” represents a methyl group.

Examples of the raw material for providing the R⁵³SiO_{1/2} unit (M unit) include organosilicon compounds such as triorganochlorosilanes, triorganoalkoxysilanes and hexaorganodisiloxanes which are represented by the following formulas, but not limited to these.

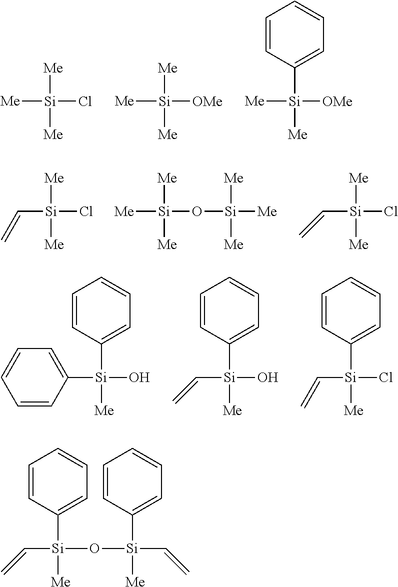

wherein “Me” represents a methyl group.

### [(B) Organohydrogenpolysiloxane]

Component (B) is an organohydrogenpolysiloxane having at least two hydrogen atoms each bonded to a silicon atom and at least one aromatic hydrocarbon group each bonded to a silicon atom. Component (B) is preferably represented by the following average compositional formula (2):

R⁷ₕHᵢSiO_{(4-h-i)/2} (2)

wherein R⁷ is, independently of each other, an unsubstituted or substituted monovalent hydrocarbon group having 1 to 10 carbon atoms, and h and i are preferably the number satisfying the equations, 0.7<=h<=2.1, 0.001<=i<=1.0 and 0.8<=h+i<=3.0, more preferably the number satisfying the equations, 1.0<=h<=2.0, 0.01<=i<=1.0 and 1.5<=h+i<=2.5.

Examples of R⁷ include saturated aliphatic hydrocarbon groups such as a methyl group, an ethyl group, a propyl group, a butyl group and a pentyl group; saturated cyclic hydrocarbon groups such as a cyclopentyl group and a cyclohexyl group; aromatic hydrocarbon groups such as aryl groups such as a phenyl group, a tolyl group and a xylyl group; aralkyl groups such as a benzyl group, a phenylethyl group and a phenylpropyl group; groups in which part or all of the hydrogen atoms bonded to the carbon atoms of the aforesaid groups are substituted with a halogen atom such as a fluorine, bromine, or chlorine atom, for instance, halogenated hydrocarbon groups such as a trifluoropropyl group and a chloropropyl group. Among these, an alkyl group having 1 to 5 carbon atoms such as a methyl group, an ethyl group and a propyl group, and a phenyl group are preferable.

Component (B) of the present invention has one or more, silicon atom-bonded aromatic hydrocarbon groups in one molecule. Thus, at least one of R⁷ is an aromatic hydrocarbon group. More preferably, component (B) has 1 to 100 aryl groups. Component (B) has at least two (usually 2 to 200), preferably three or more (usually 3 to 100) hydrogen atoms each bonded to a silicon atom to form a hydrosilyl group. Component (B) reacts with component (A) to act as a cross-linking agent.

The molecular structure of component (B) is not particularly limited, and may be any such as linear, cyclic, branched or three-dimensional network (resin) structure. The bonding point of the hydrosilyl group is not limited. For example, in a case where component (B) has a linear structure, the hydroxyl group may be bonded to a silicon atom anywhere at the molecular ends and side chains. The number of the silicon atoms in one molecule or a degree of polymerization is usually 2 to 200, preferably 3 to 100. The organohydrogenpolysiloxane is preferably liquid or solid at room temperature, i.e., 25 degrees C.

Examples of the organohydrogenpolysiloxane represented by the average composition formula (2) include tris(hydrogendimethylsiloxy)phenylsilane, methylhydrogensiloxane/diphenylsiloxane copolymers with both terminals being blocked with a trimethylsiloxy group, methylhydrogensiloxane/diphenylsiloxane/dimethylsiloxane copolymers with both terminals being blocked with a trimethylsiloxy group, methylhydrogensiloxane/methylphenylsiloxane/dimethyl siloxane copolymers with both terminals being blocked with a trimethylsiloxy group, methylhydrogensiloxane/dimethylsiloxane/diphenylsiloxane copolymers with both terminals being blocked with a dimethylhydrogensiloxy group, methylhydrogensiloxane/dimethylsiloxane/methylphenyl siloxane copolymers with both terminals being blocked with a dimethylhydrogensiloxy group and copolymers comprising (CH₃)₂HSiO_{1/2} units, SiO_{4/2} units and (C₆H₅)₃SiO_{1/2} units.

Component (B) may also be organohydrogenpolysiloxanes represented by the following formulas.

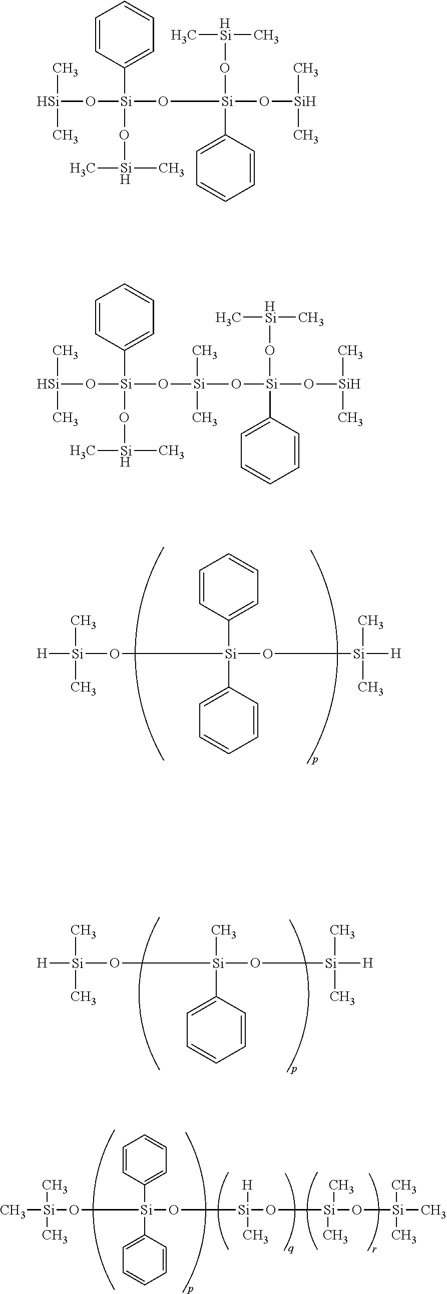

wherein p, q, r are a positive integer.

An amount of component (B) is such that a ratio of the number of the hydrosilyl group in component (B) to the number of the alkenyl group bonded to the silicon atom in component (A) is 0.1 to 4.0, preferably 0.5 to 3.0, more preferably 0.8 to 2.0. If the amount of component (B) is less than the aforesaid lower limit, the curing reaction of the present composition does not proceed enough, so that it is difficult to obtain a cured silicone product and a resulting cured product has too-low crosslink density and low mechanical strength, whereby its heat resistance is adversely affected. If the amount of component (B) is larger than the aforesaid upper limit, the large number of the hydrosilyl group remain unreacted in the cured product, so that the physical properties may change with time, the heat resistance of the cured product may be poor and, further, foam may occurs in the cured product due to dehydrogenation reaction.

When the curable organosilicon resin composition of the present invention comprises components (D) and/or (E) which will be described later, a ratio of the number of the hydrosilyl group in the composition to the total number of the silicon atom-bonded alkenyl group in the composition is 0.1 to 4.0, preferably 0.5 to 3.0, more preferably 0.8 to 2.0.

### [(C) Platinum Group Metal Catalyst]

Component (C) is a platinum group metal catalyst which accelerates the addition reaction of components (A) and (B). Any catalyst known as an addition reaction catalyst may be used. Examples of such include platinum, palladium or rhodium catalyst. In view of costs, platinum catalysts such as platinum, platinum black and chloroplatinic acid are preferable, such as, for example, H₂PtCl₆ pH₂O, K₂PtCl₆, KHPtCl₆.pH₂O, K₂PtCl₄, K₂PtCl₄.pH₂O, PtO₂.pH₂O, PtCl₄.pH₂O, PtCl₂, H₂PtCl₄.pH₂O, wherein p is a positive integer, and complexes of these catalysts with hydrocarbons such as olefins, alcohols or a vinyl group-containing organopolysiloxane. The catalyst may be used singly or in combination of two or more of them.

An amount of component (C) may be an effective amount for proceeding with the addition reaction, i.e., a catalytic amount. Generally, the amount of the catalyst is 0.1 to 500 ppm by mass as a platinum group metal, particularly 0.5 to 100 ppm by mass, based on the total mass of components (A) and (B).

The curable organosilicon resin composition of the present invention may further comprise at least one selected from the following components (D) to (F) in addition to components (A) to (C).

### [(D) Cyclic Polysiloxane]

Component (D) is a cyclic polysiloxane represented by the following formula (1):

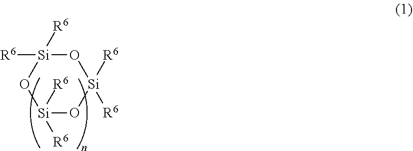

wherein R⁶ is, independently of each other, a hydrogen atom, an alkenyl group having 2 to 10 carbon atoms, a substituted or unsubstituted alkyl group having 1 to 10 carbon atoms, or an aromatic hydrocarbon group having 6 to 10 carbon atoms and n is an integer of 1 or 2. On account of the cyclic polysiloxane, the viscosity, curability and curing properties of the composition are adjusted. The alkenyl group, the alkyl group and the aromatic hydrocarbon group are those described for R¹ above. Cyclic polysiloxane (D) may adjust the viscosity, curability and curing properties of the composition.

Examples of the cyclic organopolysiloxane represented by the formula (1) include those represented by the following formulas, but are not limited thereto.

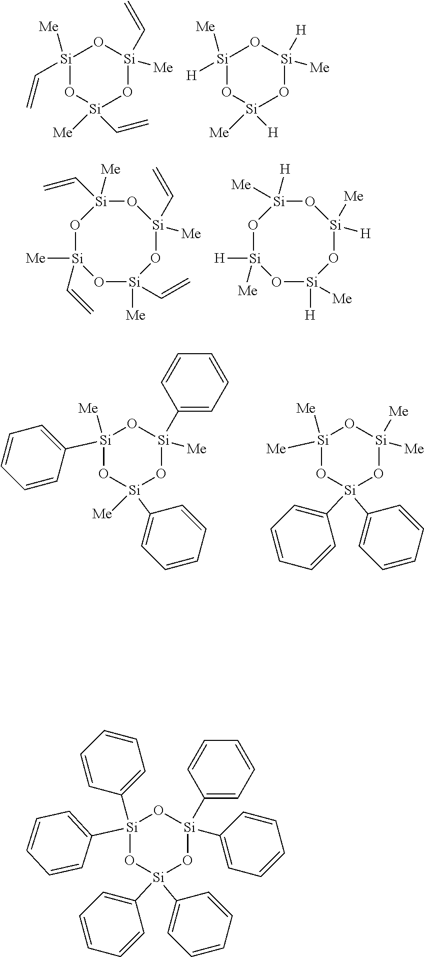

An amount of the cyclic polysiloxane is preferably 0.1 to parts by mass, more preferably 0.2 to 20 parts by mass, relative to a total 100 parts by mass of components (A) and (B). In the composition containing the aforesaid components (D) and/or (E) which will be described later, a ratio of the total number of the hydrosilyl group in the composition to the total number of the silicon atom-bonded alkenyl group in the composition is preferably 0.1 to 4.0, preferably 0.5 to 3.0, more preferably 0.8 to 2.0.

### [(E) Organopolysiloxane]

Component (E) is a linear or branched organopolysiloxane having one or more, silicon atom-bonded aromatic hydrocarbon groups having 6 to 10 carbon atoms and two or more, silicon atom-bonded alkenyl groups having 2 to 10 carbon atoms. Component (E) has a viscosity of 10 to 100,000 mPa·s at 25 degrees C. as determined according to the Japanese Industrial Standards (JIS) K 7117-1: 1999. On account of component (E), the viscosity of the composition and the hardness of the cured product can be optimally adjusted, depending on the application.

Examples of the aromatic hydrocarbon group having 6 to 10 carbon atoms, preferably 6 to 8 carbon atoms, include aryl groups such as a phenyl group, a tolyl group and a xylyl group, and aralkyl groups such as a benzyl group, a phenylethyl group and a phenylpropyl group. Among these, a phenyl group is preferable. Component (E) preferably has at least one, more preferably 2 to 100, aromatic hydrocarbon group in one molecule. Further, examples of the alkenyl group having 2 to carbon atoms, preferably 2 to 5 carbon atoms, include a vinyl group, an allyl group, a propenyl group, an isopropenyl group, a butenyl group, a hexenyl group, a cyclohexenyl group and an octenyl group. A vinyl group is preferred. Component (E) preferably has two or more, further preferably 2 to 5, alkenyl groups per molecule.

The organopolysiloxane (E) preferably has a viscosity at 25 degrees C. of 10 to 100,000 mPa·s, more preferably 100 to 50,000 mPa·s, even more preferably 1,000 to 30,000 mPa·s, as determined according to JIS K 7117-1: 1999. When the organopolysiloxane has a viscosity of 10 mPa·s or more, a cured product may not be brittle. When the organopolysiloxane has the viscosity of 100,000 mPa·s or less, good workability is attained.

Examples of (E) organopolysiloxane include compounds represented by the following formulas, but are not limited thereto.

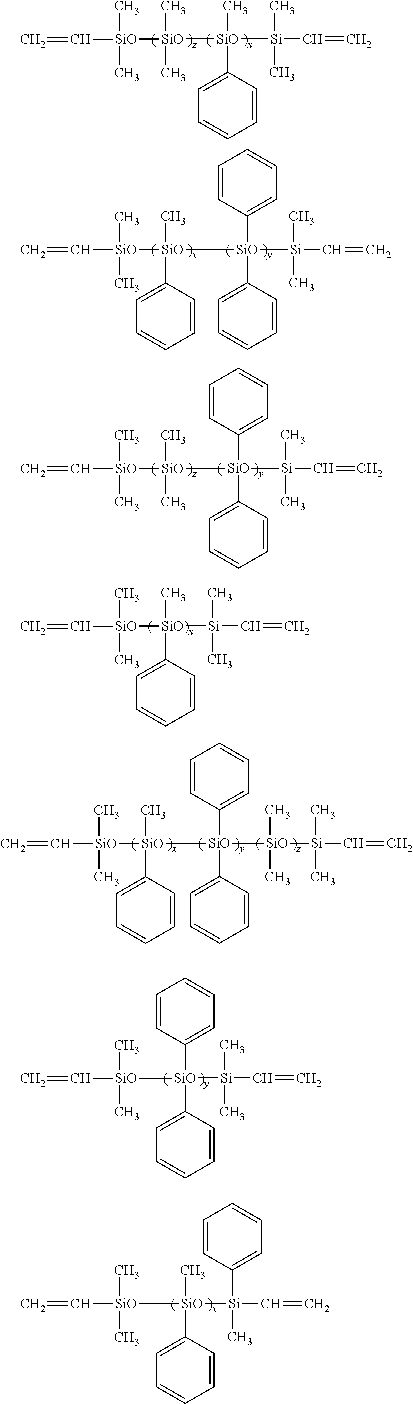

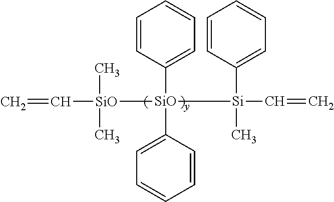

wherein x, y and z are an integer of 0 or larger, and x+y>=1.

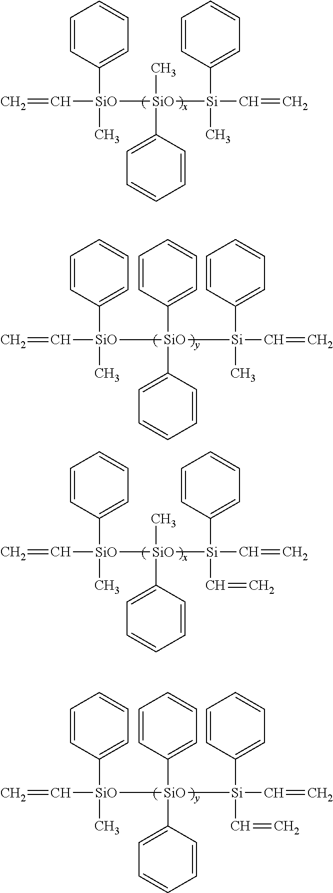

wherein x, y and z are an integer of 0 or larger, and x+y>=1.

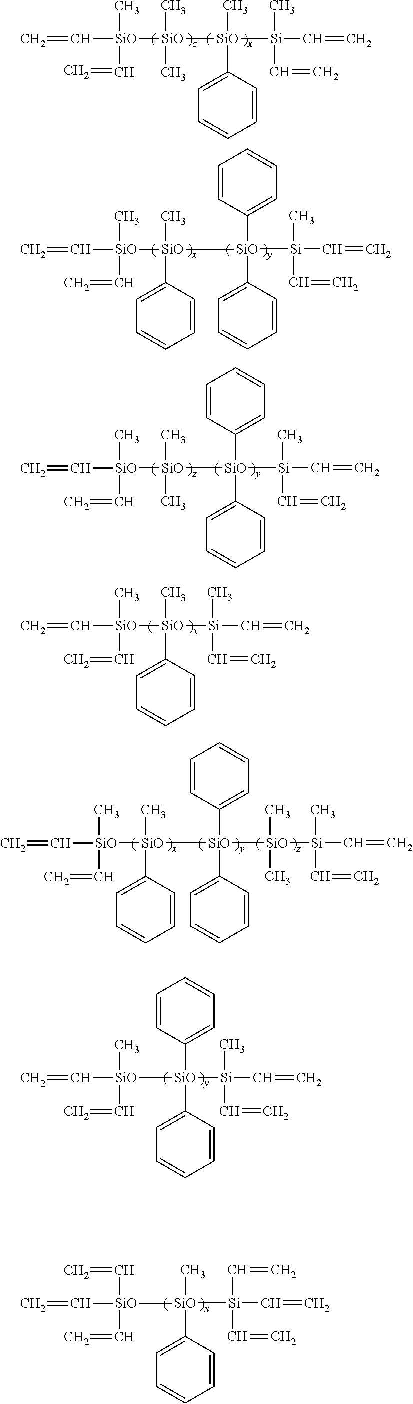

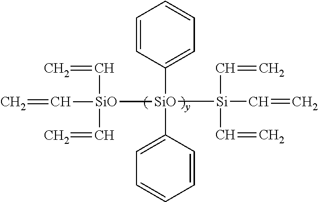

wherein x, y and z are an integer of 0 or larger, and x+y>=l.

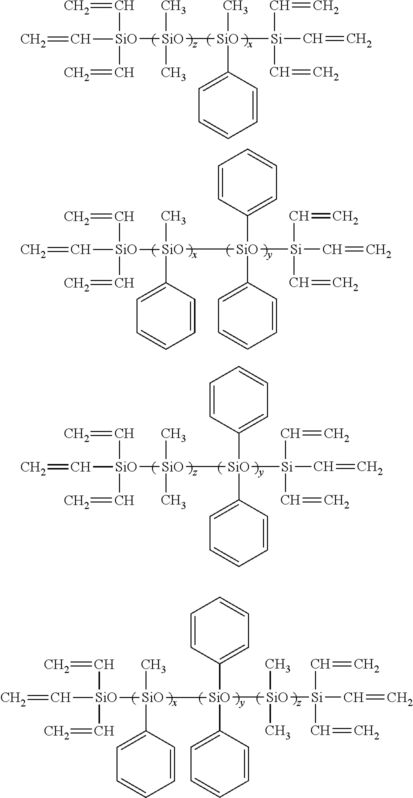

wherein x, y and z are an integer of 0 or larger, and x+y>=1.

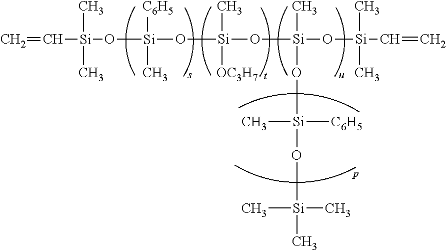

wherein s, t, u and p are an integer of 0 or larger, and s+t+u+p>=1.

An amount of (E) organopolysiloxane is preferably 0.1 to 100 parts by mass, more preferably 0.5 to 80 parts by mass, relative to total 100 parts by mass of components (A) and (B). A ratio of the number of the hydrosilyl group in the composition to the total number of the silicon atom-bonded alkyl groups in the composition is 0.1 to 4.0.

### [(F) Fluorescent Material]

The curable organosilicon resin composition of the present invention may further contain (F) fluorescent material. The curable organosilicon resin composition of the present invention is excellent in heat resistance and light resistance. Therefore, even when the composition contains a fluorescent material, no considerable decrease in fluorescent occurs in contrast with the prior art. An amount of the fluorescent material is preferably 0 to 500 parts by mass, more preferably 0 to 300 parts by mass, relative to total 100 parts by mass of components (A) to (E).

The curable organosilicon resin composition of the present invention may further comprise additives such as known adhesion-imparting agents, curing inhibitors and white pigments in addition to the components (A) to (F), if necessary.

Examples of the adhesion-imparting agents include alkoxysilanes such as phenyltrimethoxysilane, trimethoxysilane, triethoxysilane, methyldimethoxysilane, diphenyldimethoxysilane, methylphenyldimethoxysilane, vinyltrimethoxysilane, vinyltriethoxysilane, 2-(3,4-epoxycyclohexyl)ethyltrimethoxysilane, 3-glycidoxypropyltrimethoxysilane, 3-glycidoxypropylmethyldiethoxysilane, 3-glycidoxypropyltriethoxysilane, 3-methacryloxypropylmethyldiethoxysilane, 3-methacryloxypropyltriethoxysilane, N-2(aminoethyl)3-aminopropylmethyldimethoxysilane, N-2(aminoethyl)3-aminopropyltrimethoxysilane, N-2(aminoethyl)3-aminopropyltriethoxysilane, N-phenyl-3-aminopropyltrimethoxysilane, 3-mercaptopropyltrimethoxysilane, 3-isocyanatopropyltriethoxysilane, 3-cyanopropyltriethoxysilane and oligomers thereof. The adhesion-imparting agent may be used singly or in combination of two or more of them.

An amount of the adhesion-imparting agent is preferably 0 to 10 parts by mass, particularly 0 to 5 parts by mass, relative to total 100 parts by mass of components (A) and (B).

Examples of the curing inhibitors include a compound selected from the group consisting of triallyl isocyanurate, alkyl maleate, acetylene alcohols and those modified with silane or siloxane, hydroperoxide, tetramethylethylenediamine, benzotriazole and mixtures thereof. The curing inhibitor may be used singly or in combination of two or more of them. An amount of the curing inhibitor is usually 0.001 to 1.0 part by mass, preferably 0.005 to 0.5 part by mass, relative to total 100 parts by mass of components (A) and (B).

Examples of the white pigment include inorganic white pigments such as titanium oxide, zinc oxide, zirconium oxide, calcium carbonate, magnesium oxide, aluminum hydroxide, barium carbonate, magnesium silicate, zinc sulfate and barium sulfate. An amount of the white pigment may be 600 parts by mass or less, for example, 0 to 600 parts by mass, usually 1 to 600 parts by mass, preferably 10 to 400 parts by mass, relative to total 100 parts by mass of components (A) to (E).

Other additives include, for example, inorganic reinforcing fillers such as silica, glass fibers and fumed silica; inorganic non-reinforcing fillers such as calcium carbonate, calcium silicate, titanium dioxide, ferric oxide, carbon black, cerium fatty acid salts, barium fatty acid salts, cerium alkoxide and barium alkoxide; and nanofillers such as silicon dioxide (silica:SiO₂), aluminum oxide (alumina:Al₂O₃), iron oxide (FeO₂), triiron tetraoxide (Fe₃O₄), lead oxide (PbO₂), tin oxide (SnO₂), cerium oxide (Ce₂O₃, CeO₂), calcium oxide (CaO), trimanganese tetraoxide (Mn₃O₄) and barium oxide (BaO). An amount of these may be 600 parts by mass or less, for example, 0 to 600 parts by mass, usually 1 to 600 parts by mass, preferably 10 to 400 parts by mass, relative to total 100 parts by mass of components (A) to (E).

The curable organosilicon resin composition of the present invention may be applied to a desired substrate and then cured. The curable organosilicon resin composition cures sufficiently even at room temperature, 25 degrees C., but may be cured with heating, if necessary. The temperature of heating may be, for example, 60 to 200 degrees C.

The curable organosilicon resin composition of the present invention is cured with heating to provide a cured product having a thickness of 1 mm. The product preferably has a direct light transmittance of 70% or higher, more preferably 80% or higher, at wavelengths of 400 to 800 nm, particularly at a wavelength of 450 nm. The direct light transmittance may be determined by, for example, spectrophotometer U-4100, ex Hitachi, Ltd.

A cured product obtained by heat-curing the present organosilicon resin composition preferably has a refractive index of 1.43 to 1.57 at 23 degrees C. and 589 nm, as determined according to JIS K 7142:2014, A.

A cured product having such a direct light transmittance or such a refractive index is excellent in transparency and may be used particularly for optical applications, for instance, as an encapsulating material for LEDs.

The present curable organosilicon resin composition provides a cured product having excellent mechanical properties, transparency, crack resistance and heat resistance.

### <Semiconductor Device>

The present invention further provides a semiconductor device in which a semiconductor element is encapsulated with a cured product of the present curable organosilicon resin composition.

As described above, the curable organosilicon resin composition of the present invention provides a cured product having excellent transparency and heat resistance and, therefore, is suitable for lens materials for a light emitting semiconductor device, protective coating agents and molding agents. In particularly, it is useful for encapsulating LED elements such as blue LEDs, white LEDs, and ultraviolet LEDs. Even when a silicate fluorescent or a quantum dot fluorescent is added to the composition which is then used as a material for a wavelength conversion film, long-term reliability in high humidity is secured to provide a light-emitting semiconductor device having good moisture resistance and long-term color rendering, because a cured product of the present curable organosilicon resin composition has excellent heat resistance.

When a light-emitting semiconductor element such as an LED is encapsulated with the present curable organosilicon resin composition, the present curable organosilicon resin composition is applied onto an LED element mounted on a pre-mold package made of, for example, a thermoplastic resin, and cured on the LED element and, thereby, the LED element is encapsulated with a cured product of the curable organosilicon resin composition. Alternatively, the composition may be diluted with an organic solvent such as toluene, xylene, or PGMEA (propylene glycol monomethyl ether acetate) to provide a vanish, which is then applied on the LED device.

Because a cured product of the present composition has the excellent heat resistance, ultraviolet resistance, transparency, crack resistance and long-term reliability, the present curable organosilicon resin composition is suitable for optical applications such as materials for displays, light recording mediums, optical apparatus, optical components, optical fibers, and photo/electron functional organic materials, and materials for peripheral parts of integrated semiconductor circuits.

### EXAMPLES

The present invention will be explained below in further detail with reference to a series of the Examples and the Comparative Examples, though the present invention is in no way limited by these Examples.

Hereinafter, “Part” represents part by mass, “Me” represents a methyl group, “Vi” represents a vinyl group, and “Ph” represents a phenyl group. The method and the conditions for determining a weight average molecular weight are as described above. The amounts of the hydroxyl group and the alkoxy group bonded to a silicon atom were determined by ¹H-NMR and ²⁹Si-NMR.

### Example 1

Mixed were 30 parts of (A) branched phenylmethylpolysiloxane composed of 75 mol % of the PhSiO_{3/2} unit and 25 mol % of the ViPhSiO_{2/2} unit, having a weight average molecular weight of 2,500, 0.04 mol of a hydroxyl group bonded to a silicon atom and 0.06 mol of an alkoxy group bonded to a silicon atom, per 100 g of component (A); (B) organohydrogenpolysiloxane represented by the following formula (3):

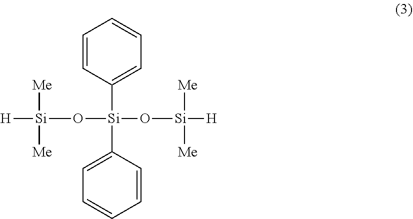 [SMILES: C[SiH](C)O[Si](O[SiH](C)C)(c1ccccc1)c1ccccc1]

in an amount such that a ratio of the number of the silicon atom-bonded hydrogen atoms in component (B) to the total number of the silicon atom-bonded vinyl groups in components (A) and (D) (hereinafter, referred to as “SiH/SiVi ratio”) was 1.0, and 0.01 part of (C) a solution of an octyl alcohol-modified chloroplatinic acid containing 1 mass % of element platinum and stirred well to obtain a curable organosilicon resin composition. The composition was heated in a mold at 150 degrees C. for 4 hours to obtain a cured product having dimensions of 120 mm×110 mm×1 mm. Its physical properties were evaluated as described below. The results are as shown in Table 1.

### Example 2

Mixed were 30 parts of (A) branched phenylmethylpolysiloxane composed of 75 mol % of the PhSiO_{3/2} unit, 1 mol % of the ViMeSiO_{2/2} unit, and 24 mol % of the ViPhMeSiO_{1/2} unit, and having a weight average molecular weight of 2,300, 0.1 mol of a hydroxyl group bonded to a silicon atom and 0.02 mol of an alkoxy group bonded to a silicon atom, per 100 g of component (A);

(B) organohydrogenpolysiloxane represented by the aforesaid formula (3) in an amount such that a ratio of the number of the silicon atom-bonded hydrogen atoms in component (B) to the total number of the silicon atom-bonded vinyl groups in the components (A) and (D) was 1.0; 0.01 part of (C) a solution of octyl alcohol-modified chloroplatinic acid containing 1 mass % of element platinum; and 2 parts of (D) cyclic polysiloxane represented by the following formula (4):

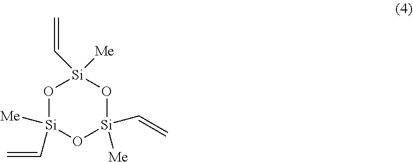

and stirred well to obtain a curable organosilicon resin composition. The composition was heated in a mold at 150 degrees C. for 4 hours to obtain a cured product having dimensions of 120 mm×110 mm×1 mm.

### Example 3

The procedures of Example 2 were repeated to obtain a cured resin composition, except that 30 parts of (A) a branched phenylmethylpolysiloxane composed of 50 mol % of the SiO_{4/2} unit, 0.1 mol % of the ViPhSiO_{2/2} unit, 25 mol % of the ViPhMeSiO_{1/2} unit, and 24.9 mol % of the PhMe₂SiO_{1/2} unit, wherein a weight average molecular weight was 4,900, the amount of the hydroxyl group bonded to a silicon atom was 0.3 mol and the amount of the alkoxy group bonded to a silicon atom was 0.3 mol, per 100 g of component (A), was used instead of component (A) used in Example 2.

### Example 4

The procedures of Example 1 were repeated to obtain a cured resin composition, except that (A) a branched phenylmethylpolysiloxane composed of 5 mol % of the SiO_{4/2} unit, 70 mol % of the PhSiO_{3/2} unit, 5 mol % of the ViMeSiO_{2/2} unit, and 20 mol % of the ViMe₂SiO_{1/2} unit, wherein a weight average molecular weight was 2,600, the amount of the hydroxyl group bonded to a silicon atom was 0.2 mol and the amount of the alkoxy group bonded to a silicon atom was 1.0 mol, per 100 g of component (A), was used instead of component (A) used in Example 1.

### Example 5

The procedures of Example 2 were repeated to obtain a cured resin composition, except that 5 parts of (D) a cyclic polysiloxane represented by the following formula (5):

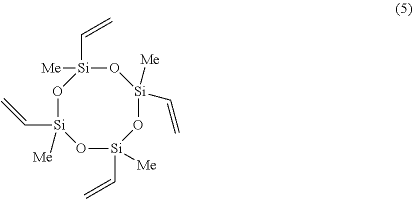 [SMILES: C=C[Si]1(C)O[Si](C)(C=C)O[Si](C)(C=C)O[Si](C)(C=C)O1]

instead of component (D) used in Example 2.

### Example 6

Mixed were 30 parts of (A) branched phenylmethylpolysiloxane composed of 75 mol % of the PhSiO_{3/2} unit, 2 mol % of the ViPhSiO_{2/2} unit, and 23 mol % of the ViPhMeSiO_{1/2} unit, having a weight average molecular weight of 2,300, 1.0 mol of a hydroxyl group bonded to a silicon atom and 0.5 mol of an alkoxy group bonded to a silicon atom, per 100 g of component (A);

(B) organohydrogenpolysiloxane represented by the following formula (4):

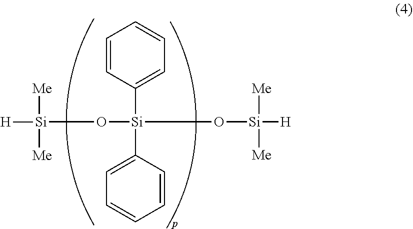

wherein p is 2 on average,

in an amount such that a ratio of the number of the silicon atom-bonded hydrogen atoms in component (B) to the total number of the silicon atom-bonded vinyl groups in components (A) and (E) was 1.0; 0.01 part of (C) a solution of octyl alcohol-modified chloroplatinic acid containing 1 mass % of element platinum; and 10 parts of (E) organopolysiloxane represented by the following formula (6):

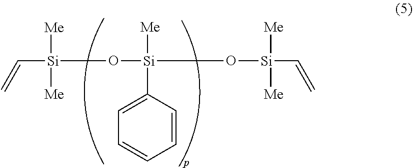

wherein p is 30 on average,

and stirred well to obtain a curable organosilicon resin composition. The composition was heated in a mold at 150 degrees C. for 4 hours to obtain a cured product having dimensions of 120 mm×110 mm×1 mm.

### Example 7

The procedures of Example 1 were repeated to obtain a cured resin composition, except that (A) a branched phenylmethylpolysiloxane composed of 5 mol % of the SiO_{4/2} unit, 70 mol % of the PhSiO_{3/2} unit, 10 mol % of the ViPhSiO_{2/2} unit, and 15 mol % of the ViMe₂SiO_{1/2} unit, wherein a weight average molecular weight was 2,200, the amount of the hydroxyl group bonded to a silicon atom was 0.7 mol and the amount of the alkoxy group bonded to a silicon atom was 1.1 mol, per 100 g of component (A), was used instead of component (A) used in Example 1.

### Example 8

The procedures of Example 1 were repeated to obtain a cured resin composition, except that (A) a branched phenylmethylpolysiloxane composed of 5 mol % of the SiO_{4/2} unit, 65 mol % of the PhSiO_{3/2} unit, 10 mol % of the ViPhSiO_{2/2} unit, and 20 mol % of the ViMe₂SiO_{1/2} unit, wherein a weight average molecular weight was 2,700, the amount of the hydroxyl group bonded to a silicon atom was 1.2 mol and the amount of the alkoxy group bonded to a silicon atom was 0 mol, per 100 g of component (A), instead of component (A) used in Example 1.

### Example 9

Mixed were 30 parts of (A) branched phenylmethylpolysiloxane composed of 75 mol % of the PhSiO₃₁₂ unit, 5 mol % of the ViPhSiO_{2/2} unit, and 20 mol % of the ViPhMeSiO_{1/2} unit, having a weight average molecular weight of 2,500, 0.03 mol of a hydroxyl group bonded to a silicon atom, 0.05 mol of an alkoxy group bonded to a silicon atom, per 100 g of component (A);

(B) organohydrogenpolysiloxane represented by the following formula (3):

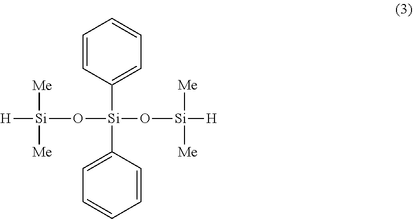 [SMILES: C[SiH](C)O[Si](O[SiH](C)C)(c1ccccc1)c1ccccc1]

in an amount such that a ratio of the number of the silicon atom-bonded hydrogen atoms in component (B) to the number of the silicon atom-bonded vinyl groups in the component (A) is 1.0; 0.01 part of (C) a solution of octyl alcohol-modified chloroplatinic acid containing 1 mass % of element platinum; and 200 parts of inorganic white pigment, CR-90, ex ISHIHARA SANGYO KAISHA, LTD., relative to the total 100 parts of components (A) to (C), and well stirred to obtain a curable organic silicon resin composition.

The composition was heated in a mold at 150 degrees C. for 4 hours to obtain a cured product having dimensions of 120 mm×110 mm×1 mm. Its physical properties were determined. The results are as shown in Table 1.

### Comparative Example 1

The procedures of Example 1 were repeated to obtain a cured resin composition, except that use was made of branched phenylmethylpolysiloxane composed of 80 mol % of the PhSiO_{3/2} unit and 20 mol % of the ViPhMeSiO_{1/2} unit, wherein a weight average molecular weight was 2,000, the amount of the hydroxyl group bonded to a silicon atom was 0.5 mol and the amount of the alkoxy group bonded to a silicon atom was 0.05 mol, per 100 g of the branched phenylmethylpolysiloxane, instead of component (A) used in Example 1.

### Comparative Example 2

The procedures of Example 1 were repeated to obtain a cured resin composition, except that use was made of a branched phenylmethylpolysiloxane composed of 80 mol % of the PhSiO_{3/2} unit, 0.05 mol % of the ViPhSiO_{2/2} unit, and 19.95 mol % of the ViMe₂SiO_{1/2} unit, wherein a weight average molecular weight was 2,100, the amount of the hydroxyl group bonded to a silicon atom was 0.1 mol and the amount of the alkoxy group bonded to a silicon atom was 0.05 mol, per 100 g of the branched phenylmethylpolysiloxane, instead of component (A) used in Example 1.

### Comparative Example 3

The procedures of Example 1 were repeated to obtain a cured resin composition, except that use was made of a branched phenylmethylpolysiloxane composed of a 10 mol % of the SiO_{4/2} unit, 35 mol % of the PhSiO_{3/2} unit, 25 mol % of the ViPhSiO_{2/2} unit, and 30 mol % of the Me₃SiO_{1/2} unit, wherein a weight average molecular weight was 3,000, the amount of the hydroxyl group bonded to a silicon atom was 0.05 mol and the amount of the alkoxy group bonded to a silicon atom was 0.04 mol, per 100 g of the branched phenylmethylpolysiloxane, instead of the component (A) used in Example 1.

### Comparative Example 4

The procedures of Example 1 were repeated to obtain a cured resin composition, except that use was made of a branched phenylmethylpolysiloxane composed of 65 mol % of the PhSiO_{3/2} unit, 10 mol % of the ViPhSiO_{2/2} unit, and 25 mol % of the ViPhMeSiO_{1/2} unit, wherein a weight average molecular weight was 2,300, the amount of the hydroxyl group bonded to a silicon atom was 0.0005 mol and the amount of the alkoxy group bonded to a silicon atom was 0.05 mol, per 100 g of the branched phenylmethylpolysiloxane, instead of component (A) used in Example 1.

### Comparative Example 5

The procedures of Example 1 were repeated to obtain a cured resin composition, except that use was made of a branched phenylmethylpolysiloxane composed of 10 mol % of the SiO_{4/2} unit, 45 mol % of the Ph₂SiO_{2/2} unit, 20 mol % of the Ph₂SiO_{2/2} unit, and 25 mol % of the ViMe₂SiO_{1/2} unit, wherein a weight average molecular weight was 3,000, its fraction having a weight average molecular weight of 5,000 or more was contained at 11.3%, the amount of the hydroxyl group bonded to a silicon atom was 0.2 mol and the amount of the alkoxy group bonded to a silicon atom was 0.04 mol, per 100 g of the branched phenylmethylpolysiloxane, instead of component (A) used in Example 1.

The properties of the curable organosilicon resin compositions and the cured products obtained in the above-mentioned Examples and Comparative Examples were evaluated according to the following manners. The results are as shown in Tables 1 and 2.

### (1) Appearance

Color and transparency were visually observed on the cured product which had a thickness of 1 mm and was prepared by curing the composition at 150 degrees C. for 4 hours.

### (2) Fluidity

The fluidity of the composition before cured was observed as follows.

50 Grams of the composition was added to a 100 milliliter-glass bottle. The glass bottle was laid down sideways and left as such at 25 degrees C. for 10 minutes. If the resin flowed out during this period of time, the composition was judged to be in a liquid state.

### (3) Viscosity

The viscosity of the composition before cured was determined at 25 degrees C. according to the Japanese Industrial Standards, JIS, K 7117-1: 1999.

### (4) Refractive Index

The refractive index of the composition before cured was determined with a light having a wavelength of 589 nm at 25 degrees C. by a digital refractometer RX-9000a, ex ATAGO CO., LTD.

### (5) Hardness, Type D

The hardness of the cured product obtained by curing the composition at 150 degrees C. for 4 hours was determined by a durometer D hardness meter in accordance with JIS K 6249:2003.

### (6) Elongation at Break and Tensile Strength

The elongation at break and the tensile strength of the cured product obtained by curing the composition at 150 degrees C. for 4 hours were determined according to JIS K 6249:2003.

### (7) Surface Tackiness

The surface of the cured product having a thickness of 1 mm obtained by curing the composition at 150 degrees C. for 4 hours was touched by fingers, and the tackiness was evaluated according to the following criteria.

A: No tackiness

B: Slight tackiness

C: Considerable tackiness

### (8) Adhesiveness

0.25 Gram of the composition was shaped to have a bottom area of 45 mm² on a silver plate having an area of 180 mm², and cured at 150 degrees C. for 4 hours. Then, the cured product was broken and removed by a micro spatula. An area of cohesive fracture and an area of peeling were determined. The adhesiveness was evaluated according to the following criteria.

A: Good adhesiveness
(the area of the cohesive fracture >=60%)

B: Poor adhesiveness
(the area of the cohesive fracture <60%)
   The presence or absence of dust was visually observed on the surface of the cured product obtained by curing the composition at 150 degrees C. for 4 hours.

### (9) Gas Barrier Property

The composition was poured in a silver-plated plate having a base area of 1 cm² and a depth of 0.6 mm, and cured at 150 degrees C. for 4 hours. The obtained cured product on the silver-plated plate were placed together with 3 g of sulphur powder in a sealed container and left in a constant temperature bath having 80 degrees C. for 50 hours. Thereafter, the reflectivity on the silver-plated plate was determined using a spectrophotometer, Color 8200, ex X-Rite Corporation.

For the composition of Example 9, the cured product was stripped from the silver-plated plate after the sulfurization step, and the reflectance on the silver-plated plate was determined. The results were evaluated according to the following criteria.

The initial reflectance immediately after curing of each sample was 90%.
A: Reflectance was 85% or more
B: Reflectance was 75% or more and less than 85%
C: Reflectance was less than 75%

### (10) Heat Resistance (Less Change in Light Transmittance or Reflectance)

The light transmittance of a cured product having a thickness of 1 mm obtained by curing the compositions at 150 degrees C. for 4 hours was determined at 450 nm at 23 degrees C. by Hitachi Spectrophotometer U-4100, hereinafter referred to as an initial transmittance. The initial transmittances of each of the cured products are as shown in Tables 1 and 2.

Then, the cured product was heat-treated at 200 degrees C. for 1,000 hours, and the light transmittance was determined in the same manner as the initial transmittance. Percentage of the light transmittance after the heat treatment, relative to the initial transmittance was calculated and evaluated according to the following criteria.

A: The percentage was 90% or more.
B: The percentage was less than 90% to 80% or more.
C: The percentage was less than 80%.

Since the curable organosilicon composition obtained in Example 9 comprised the white pigment, the reflectance on the cured product was determined at 450 nm, instead of a transmittance, by a spectrophotometer, Color 8200, ex X-Rite Corporation, hereinafter referred to as initial reflectance.

Then, the cured product was heat-treated at 200 degrees C. for 1,000 hours, and the reflectance was determined in the same manners as the initial reflectance. Percentage of the reflectance after the heat treatment, relative to the initial transmittance was calculated and evaluated according to the following criteria.

A: The percentage was 90% or more.
B: The percentage was less than 90% to 80% or more.
C: The percentage was less than 80%.

TABLE 1

| | | EXAMPLE | | | | |
|---|---|---|---|---|---|---|
| | | 1 | 2 | 3 | 4 | 5 |
| (A) Branched | Q unit | 0 | 0 | 50 | 5 | 0 |
| organopolysiloxane | (SiO_{4/2}), mol % | | | | | |
| | T unit | 75 | 75 | 0 | 70 | 75 |
| | (PhSiO_{3/2}), mol % | | | | | |
| | D unit | 25 | 1 | 0.1 | 5 | 1 |
| | (ViPhSiO_{2/2}), mol % | | | | | |
| | M unit | 0 | 24 | 25 | 20 | 24 |
| | (ViPhMeSiO_{1/2}), mol % | | | | | |
| | M units | | | 24.9 | | |
| | (PhMe₂SiO_{1/2}), mol % | | | | | |
| | Amount of the aryl group, | 80 | 66 | 33 | 68 | 67 |
| | mol % | | | | | |
| | Weight-average molecular | 2500 | 2300 | 4900 | 2600 | 2300 |
| | weight | | | | | |
| | SiOH, mo1/100 g | 0.04 | 0.1 | 0.3 | 0.2 | 0.1 |
| | SiOR, mol/100 g | 0.06 | 0.02 | 0.3 | 1 | 0.02 |
| Evaluation | Appearance | Colorless | Colorless | Colorless | Colorless | Colorless |
| | | and | and | and | and | and |
| | | transparent | transparent | transparent | transparent | transparent |
| | Fluidity | Liquid | Liquid | Liquid | Liquid | Liquid |
| | Viscosity, Pa · s | 5 | 2 | 3 | 5 | 2 |
| | Refractive index | 1.55 | 1.54 | 1.54 | 1.54 | 1.54 |
| | Transmittance, % | 99 | 99 | 99 | 98 | 98 |
| | Reflectance, % | — | — | — | — | — |
| | Hardness, type D, at 150 | 73 | 70 | 62 | 70 | 72 |
| | degrees C. × 4 h | | | | | |
| | Elongation at break, % | 55 | 50 | 45 | 60 | 55 |
| | Tensile strength, MPa | 12 | 10 | 7 | 8 | 9 |
| | Surface tackiness | A | A | A | A | A |
| | Adhesiveness to Ag | A | A | A | A | A |
| | Gas barrier | A | A | A | A | A |
| | property | | | | | |
| | Heat resistance | A | A | A | A | A |

| | | EXAMPLE | | | |
|---|---|---|---|---|---|
| | | 6 | 7 | 8 | 9 |
| (A) Branched | Q unit | 0 | 5 | 5 | 0 |
| organopolysiloxane | (SiO_{4/2}), mol % | | | | |
| | T unit | 75 | 70 | 65 | 75 |
| | (PhSiO_{3/2}), mol % | | | | |
| | D unit | 2 | 10 | 10 | 5 |
| | (ViPhSiO_{2/2}), mol % | | | | |
| | M unit | 23 | 15 | 20 | 20 |
| | (ViPhMeSiO_{1/2}), mol % | | | | |
| | M units | | | | |
| | (PhMe₂SiO_{1/2}), mol % | | | | |
| | Amount of the aryl group, | 67 | 70 | 66 | 69 |
| | mol % | | | | |
| | Weight-average molecular | 2300 | 2200 | 2700 | 2500 |
| | weight | | | | |
| | SiOH, mo1/100 g | 1 | 0.7 | 1.2 | 0.3 |
| | SiOR, mol/100 g | 0.5 | 1.1 | 0 | 0.5 |
| Evaluation | Appearance | Colorless | Colorless | Colorless | White |
| | | and | and | and | |
| | | transparent | transparent | transparent | |
| | Fluidity | Liquid | Liquid | Liquid | Liquid |
| | Viscosity, Pa · s | 4 | 4 | 3 | 45 |
| | Refractive index | 1.55 | 1.54 | 1.54 | 1.54 |
| | Transmittance, % | 99 | 98 | 99 | — |
| | Reflectance, % | — | — | — | 97 |
| | Hardness, type D, at 150 | 55 | 65 | 65 | 80 |
| | degrees C. × 4 h | | | | |
| | Elongation at break, % | 60 | 45 | 40 | 30 |
| | Tensile strength, MPa | 7 | 8 | 7 | 20 |
| | Surface tackiness | A | B | B | A |
| | Adhesiveness to Ag | A | A | A | A |
| | Gas barrier | A | A | A | A |
| | property | | | | |
| | Heat resistance | A | A | A | A |

TABLE 2

| | | COMPARATIVE EXAMPLE | | | | |
|---|---|---|---|---|---|---|
| | | 1 | 2 | 3 | 4 | 5 |
| Branched chain | Q unit | 0 | 0 | 10 | 0 | 10 |
| organopolysiloxane | (SiO_{4/2}), mol % | | | | | |
| | T unit | 80 | 80 | 35 | 65 | 0 |
| | (PhSiO_{3/2}), mol % | | | | | |
| | D unit | 0 | 0.05 | 25 | 10 | 0 |
| | (ViPhSiO_{2/2}), | | | | | |
| | mol % | | | | | |
| | D unit | 0 | 0 | 0 | 0 | 65 |
| | (Ph₂SiO_{2/2}), | | | | | |
| | mol % | | | | | |
| | M unit | 20 | 19.95 | | 25 | 25 |
| | (ViPhMeSiO_{1/2}), | | | | | |
| | mol % | | | | | |
| | M units | | | 30 | | |
| | (PhMe₂SiO_{1/2}), | | | | | |
| | mol % | | | | | |
| | Amount of the aryl | 72 | 72 | 34 | 63 | 76 |
| | group, | | | | | |
| | mol % | | | | | |
| | Weight-average | 2000 | 2100 | 3100 | 3000 | 2300 |
| | molecular weight | | | | | |
| | SiOH, mol/100 g | 0.5 | 0.1 | 0.05 | 0.0005 | 0.2 |
| | SiOR, mol/100 g | 0.05 | 0.05 | 0.2 | 0.04 | 0.05 |
| Evaluation | Appearance | Colorless | Colorless | Colorless | Colorless | Colorless |
| | | and | and | and | and | and |
| | | transparent | transparent | transparent | transparent | transparent |
| | Fluidity | Liquid | Liquid | Liquid | Liquid | Liquid |
| | Viscosity, Pa · s | 4 | 5 | 3 | 3 | 2 |
| | Refractive index | 1.55 | 1.55 | 1.53 | 1.54 | 1.54 |
| | Transmittance, % | 98 | 99 | 98 | 99 | 99 |
| | Reflectance, % | 70 | 71 | 25 | 60 | 25 |
| | Hardness, type D, at | 35 | 40 | 50 | 40 | 60 |
| | 150 degrees C. × 4 h | | | | | |
| | Elongation at | 10 | 12 | 2 | 8 | 3 |
| | break, % | | | | | |
| | Tensile strength, | A | A | C | A | A |
| | MPa | | | | | |
| | Surface tackiness | A | A | A | C | A |
| | Adhesiveness to Ag | B | B | C | A | C |
| | Gas barrier | C | B | A | A | C |
| | property | | | | | |

As seen in Table 2, the cured product obtained from the organosilicon resin composition of Comparative Example 1 which contained the organopolysiloxane having no alkenyl group-containing D unit and the cured product obtained from the organosilicon resin composition of Comparative Example 2 which contained a too little amount of the alkenyl group-containing D unit had the inferior gas barrier property and heat resistance. The cured product obtained from the organosilicon resin composition of Comparative Example 3 which comprised the organopolysiloxane in which the total amount of Q unit and T unit was less than 50 mol % was inferior in the gas barrier property.

In addition, in the cured product obtained from the composition of Comparative Example 4 in which the amount of the silicon atom-bonded hydroxyl group contained in the organopolysiloxane resin was less than 0.001 mol/100 g, the adhesiveness was lower.

In contrast, as seen in Table 1, the cured products from the curable organosilicon resin composition of the present invention was colorless and transparent, had sufficient hardness, elongation at break and tensile strength, good heat resistance, gas barrier property and adhesiveness. In particular, the curable organosilicon resin compositions of Examples 1 to 6 provided the cured products having the above-mentioned excellent characteristics and no adherence of dust due to a tacky surface, on account of the specified amounts of the hydroxyl and alkoxy groups each bonded to the silicon atom.

### INDUSTRIAL APPLICABILITY

The curable organosilicon resin composition of the present invention is flowable, quickly cures to provide a cured product having excellent mechanical properties, heat resistance, and gas barrier property. The present curable organosilicon resin composition is suitable as encapsulating materials for semiconductor devices providing a semiconductor element such as a light-emitting element.

1. A curable organosilicon resin composition comprising
(A) an organopolysiloxane having at least two alkenyl groups each bonded to a silicon atom, and comprising 0.1 to 30 mol % of R²R³SiO_{2/2} units based on the total mole of siloxane units and at least one out of an SiO_{4/2} unit and a R¹SiO_{3/2} unit, wherein the total mole of the SiO_{4/2} unit and the R¹SiO_{3/2} unit is 50 mol % or more based on the total mole of the siloxane units,
wherein, R¹ is, independently of each other, a substituted or unsubstituted alkyl group having 1 to 10 carbon atoms, an alkenyl group having 2 to 10 carbon atoms, or an aromatic hydrocarbon group having 6 to 10 carbon atoms, R² is, independently of each other, an alkenyl group having 2 to 10 carbon atoms, and R³ is, independently of each other, a substituted or unsubstituted alkyl group having 1 to 10 carbon atoms, or an aromatic hydrocarbon group having 6 to 10 carbon atoms,
wherein a hydroxyl group is bonded to a silicon atom in an amount of at least 0.001 mol/100 g of the organopolysiloxane;
(B) an organohydrogenpolysiloxane having at least two hydrogen atoms each bonded to a silicon atom and at least one aromatic hydrocarbon group each bonded to a silicon atom in an amount such that a ratio of the number of the hydrosilyl group in component (B) to the number of the alkenyl group in component (A) is 0.1 to 4.0; and
(C) a platinum group metal catalyst in a catalytic amount.

2. The curable organosilicon resin composition according to claim 1, wherein component (A) comprises 0 to 60 mol % of the SiO_{4/2} unit, 0 to 90 mol % of the R¹SiO_{3/2} unit, with a total mole of the SiO_{4/2} unit and the R¹SiO_{3/2} unit being 50 mol % or more, 0.1 to 30 mol % of the R²R³SiO_{2/2} unit, 0 to 50 mol % of (R⁴)2SiO_{2/2} unit, and 0 to 50 mol % of (R⁵)₃SiO_{1/2} unit, based on the total mole of the siloxane units, and 0.001 to 1.0 mol of a silicon atom-bonded hydroxyl group and 1.0 mol or less of a silicon atom-bonded alkoxy group having 1 to 10 carbon atoms per 100 g of component (A), wherein component (A) has a weight average molecular weight of 1,000 to 5,000,
wherein R¹, R² and R³ are as defined above, R⁴ is, independently of each other, a substituted or unsubstituted alkyl group having 1 to 10 carbon atoms or an aromatic hydrocarbon group having 6 to 10 carbon atoms, R⁵ is, independently of each other, an alkenyl group having 2 to 10 carbon atoms, a substituted or unsubstituted alkyl group having 1 to 10 carbon atoms, or an aromatic hydrocarbon group having 6 to 10 carbon atoms, and at least one of R⁵'s is an alkenyl group having 2 to 10 carbon atoms.

3. The curable organosilicon resin composition according to claim 1, wherein R² is a vinyl group and R³ is a methyl group or a phenyl group in the R²R³SiO_{2/2} unit of component (A).

4. The curable organosilicon resin composition according to claim 1, further comprising (D) a cyclic siloxane represented by the following formula (1): 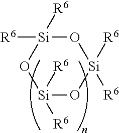
wherein R⁶ is, independently of each other, a hydrogen atom, an alkenyl group having 2 to 10 carbon atoms, a substituted or unsubstituted alkyl group having 1 to 10 carbon atoms, or an aromatic hydrocarbon group having 6 to 10 carbon atoms, and n is 1 or 2,
in an amount of 0.1 to 30 parts by mass, relative to total 100 parts by mass of components (A) and (B),
provided that when component (D) has an alkenyl group and/or a hydrosilyl group, a ratio of the number of the hydrosilyl group in components (B) and (D) to the total number of the alkenyl group in components (A) and (D) is 0.1 to 4.0.

5. The curable organosilicon resin composition according to claim 1, further comprising (E) a linear or branched organopolysiloxane having at least one silicon atom-bonded aromatic hydrocarbon group having 6 to 10 carbon atoms, at least two silicon atom-bonded alkenyl groups having 2 to 10 carbon atoms and having a viscosity at 25 degrees C. of 10 to 100,000 mPa·s as determined according to JIS K 7117-1: 1999, in an amount of 0.1 to 100 parts by mass, relative to total 100 parts by mass of components (A) and (B),
wherein a ratio of the number of the hydrosilyl group in the composition to the total number of the alkenyl group in the composition is 0.1 to 4.0.

6. The curable organosilicon resin composition according to claim 1, further comprising at least one inorganic white pigment.

7. A semiconductor device having a cured product of the curable organosilicon resin composition according to claim 1 and a semiconductor element.

8. A semiconductor device having a cured product of the curable organosilicon resin composition according to claim 1 and a semiconductor element, wherein the cured product has a direct light transmittance of 70% or more at a wavelength of 450 nm and a thickness of 1 mm.

9. The semiconductor device according to claim 7, wherein the semiconductor element is a light emitting element.
